(19) United States
(12) Patent Application Publication
(10) Pub. No.: US 2024/0310452 A1
(43) Pub. Date: Sep. 19, 2024

(54) SECONDARY BATTERY DIAGNOSIS METHOD, SECONDARY BATTERY DIAGNOSIS DEVICE, AND SECONDARY BATTERY DIAGNOSIS SYSTEM

(71) Applicant: KABUSHIKI KAISHA TOSHIBA, Tokyo (JP)

(72) Inventors: Kakuya UEDA, Kawasaki Kanagawa (JP); Yoshiaki MURATA, Kawasaki Kanagawa (JP); Yasunobu YAMASHITA, Meguro Tokyo (JP); Taro FUKAYA, Setagaya Tokyo (JP)

(73) Assignee: KABUSHIKI KAISHA TOSHIBA, Tokyo (JP)

(21) Appl. No.: 18/581,459

(22) Filed: Feb. 20, 2024

(30) Foreign Application Priority Data
Mar. 15, 2023 (JP) 2023-040593

(51) Int. Cl. G01R 31/385; B65D 81/18; G01R 31/36; G01R 31/367; H02J 7/00

(52) U.S. Cl. CPC G01R 31/386; B65D 81/18; G01R 31/3648; G01R 31/367; H02J 7/0069; B65D 2585/88

(57) ABSTRACT

A secondary battery diagnosis method rapidly charges a secondary battery at a low temperature and stores the secondary battery in a range of 45° C. or higher and 70° C. or lower for a predetermined period. The method determines a degree of voltage drop of the secondary battery between before and after storing the secondary battery. The secondary battery includes a negative electrode in which an active material having an average operating potential of 1.0 VvsLi/Li⁺ or more occupies 50% by weight or more of a negative electrode active material-containing layer.

### CROSS-REFERENCE TO RELATED APPLICATIONS

This application is based upon and claims the benefit of priority from Japanese Patent Application No. 2023-040593 filed on Mar. 15, 2023, and the entire contents of which are incorporated herein by reference.

### FIELD

Embodiments described herein relate generally to a secondary battery diagnosis method, a secondary battery diagnosis device, and a secondary battery diagnosis system.

### BACKGROUND

A lithium ion secondary battery such as a nonaqueous electrolyte battery is a rechargeable battery in which lithium ions move between a positive electrode and a negative electrode to perform charge-discharge.

The positive electrode and the negative electrode hold a nonaqueous electrolyte containing lithium ions.

The nonaqueous electrolyte battery is expected to be used not only as a power source for small electronic devices but also as a medium-to-large power source for in-vehicle applications and stationary applications and the like.

As an active material of the lithium ion secondary battery, use of a niobium-titanium-based oxide has been recently studied.

This is because the niobium-titanium-based oxide is expected to have a high charge-discharge capacity. However, in the secondary battery, there is a problem that a certain number of batteries whose battery voltage decreases with charge-discharge occur. Therefore, it is required to quickly detect an abnormal cell as described above.

### BRIEF DESCRIPTION OF THE DRAWINGS

FIGS. 1A and 1B are schematic views illustrating a part of a secondary battery diagnosis method according to an embodiment;

FIGS. 2A and 2B are schematic views illustrating another part of the secondary battery diagnosis method according to the embodiment;

FIG. 3 is a flowchart illustrating an example of the secondary battery diagnosis method according to the embodiment;

FIG. 4 specifically illustrates an example of a recycling system for recovering a niobium-titanium oxide from a battery;

FIG. 5 is a flowchart illustrating an example of a recycling method using the recycling system of FIG. 4;

FIG. 6 is a cross-sectional view schematically illustrating an example of a secondary battery in which the secondary battery diagnosis method of the present embodiment is used;

FIG. 7 is a cross-sectional view of the secondary battery illustrated in FIG. 6 and taken along line II-II;

FIG. 8 is a block diagram illustrating an example of the schematic configuration of a secondary battery diagnosis device according to the present embodiment;

FIG. 9 is a block diagram illustrating another example of the schematic configuration of the secondary battery diagnosis device according to the present embodiment; and

FIG. 10 is a block diagram schematically illustrating the secondary battery diagnosis system according to the present embodiment.

### DETAILED DESCRIPTION

Hereinafter, embodiments will be described with reference to the drawings. In the following description, components that exhibit the same or similar functions are denoted by the same reference numerals throughout all the drawings, and redundant description will be omitted. Each drawing is a schematic view for promoting the description of the embodiment and the understanding thereof, and the shape, size, and ratio and the like are different from those of the actual device, but these can be appropriately modified in design in consideration of the following description and known techniques.

### First Embodiment

According to a first embodiment, there is provided a secondary battery diagnosis method including: rapidly charging a secondary battery at a low temperature; storing the secondary battery in a range of 45° C. or higher and 70° C. or lower for a predetermined period; and determining a degree of voltage drop of the secondary battery before and after storing the secondary battery. The secondary battery includes a negative electrode in which an active material having an average operating potential of 1.0 VvsLi/Li⁺ or more occupies 50% by weight or more of a total weight of a negative electrode active material-containing layer.

By the secondary battery diagnosis method described above, it is possible to detect a battery whose battery voltage decreases as it charges and discharges in a short time.

First, the fact that the battery voltage of a lithium ion secondary battery decreases with charge-discharge will be described. Generally, by charging and discharging the lithium ion secondary battery, an active material stores and releases lithium ions, and the lithium ions move between the active materials of positive and negative electrodes. Since the store and release of lithium ions in the active material generate a dynamic load on the active material, the expansion and contraction of the positive and negative electrodes are caused by charging and discharging the battery. For example, when a foreign matter enters between the positive and negative electrodes and a separator, a pressure is generated between the positive and negative electrodes and the separator by the volume change of the positive and negative electrodes described above and by laminating or winding the positive and negative electrodes with the separator interposed therebetween. When this pressure exceeds the strength of the separator, the foreign matter may penetrate the separator. When the foreign matter is a metal or a material constituting the positive and negative electrodes, the foreign matter penetrates the separator and reaches a counter electrode, thereby causing the internal short circuit of the battery, resulting in a decrease in the battery voltage.

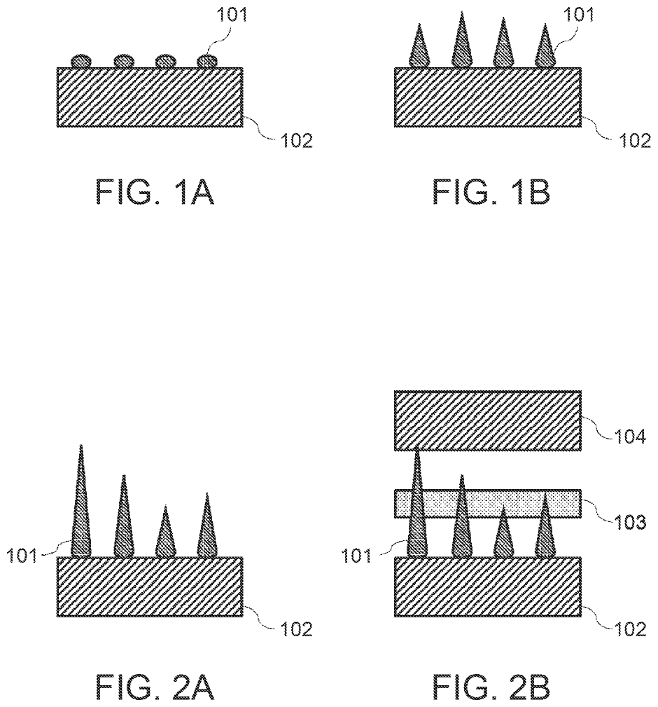

With respect to the battery in which the above phenomenon occurs, the secondary battery diagnosis method according to the present embodiment can detect a battery whose battery voltage decreases with future charge-discharge in a short time. FIG. 1 is a schematic view illustrating a part of a secondary battery diagnosis method according to an embodiment. FIG. 2 is a schematic view illustrating another part of the secondary battery diagnosis method according to the embodiment. A flow of detecting a battery whose battery voltage decreases with charge-discharge is performed in the order of FIG. 1A, FIG. 1B, FIG. 2A, and FIG. 2B.

FIG. 1A illustrates a state where a foreign matter 101 is present between an electrode 102 and a separator (not illustrated). Since the foreign matter 101 is present between the electrode 102 and the separator, there is a possibility that the foreign matter 101 penetrates the separator during future charge-discharge of the battery, and the foreign matter 101 reaches the counter electrode, thereby causing an internal short circuit. In FIG. 1A, the foreign matter 101 is represented in an elliptical shape, but the shape of the foreign matter 101 is not particularly limited, and may be, for example, a spherical shape, a flat shape, or a fibrous shape or the like. The foreign matter 101 has a total weight ratio of Mn, Fe, Co, and Ni contained in an active material-containing layer of 50 ppm or more with respect to the active material contained in the active material-containing layer. The foreign matter 101 may be referred as a precipitation substance or a precipitation metal.

In FIG. 1B, by rapidly charging the battery at a low temperature, the growth of the foreign matter 101 present in FIG. 1A into a dendrite crystal can be caused to proceed. In this low-temperature rapid charge, it is preferable that, under the condition state of charge (SOC) 90% in a range of −25° C. or higher and 25° C. or lower, a constant current value of 0.4x or more and 1.3x or less is applied to the secondary battery for 10 seconds or more and 30 seconds or less, where x (mA/cm²) is a value obtained by dividing a current value corresponding to 10C with respect to a cell capacity by an electrode facing area. That is, it is preferable to apply a constant current whose current density is 0.4x or more and 1.3x or less. The temperature and the current will be described later. When the low-temperature rapid charge is applied to the secondary battery, crystals can be sufficiently grown in a short time during storage to be described later, and an internal short circuit can be caused, so that the diagnosis of the secondary battery becomes possible.

FIG. 2A illustrates a state where the crystal growth is caused to further proceed by storing the battery after being rapidly charged at a low temperature in FIG. 1B. The battery is stored for a predetermined time in a range of 45° C. or higher and 70° C. or lower. Specifically, the secondary battery is stored for 240 hours (ten days). This time can be changed by setting a threshold value in the subsequent determination. Since a side reaction can be suppressed during storage, it is preferable to store the secondary battery in a state where no current is applied. Here, the voltage V0 of the secondary battery is measured on the 0th day of storage of the battery, that is, in a state before starting the storage.

FIG. 2B illustrates a state where a decrease in the battery voltage of the secondary battery is finally detected in the secondary battery diagnosis method of the present embodiment. In FIG. 2B, due to the growth of the crystal in the storage described above, the crystal penetrates the separator 103 and reaches the counter electrode 104, thereby causing an internal short circuit, resulting in the decrease in the battery voltage. In the decrease in the battery voltage, the voltage V1 of the secondary battery on the tenth day of storage is measured, and a difference between V0 and V1 described above is calculated, so that the secondary battery is determined as a target battery when the difference is equal to or greater than a threshold value. The target battery is a battery to be replaced, but is not necessarily a defective battery. For example, the target battery can be reused as another battery application, or a reusable portion can be recycled from the electrode 102.

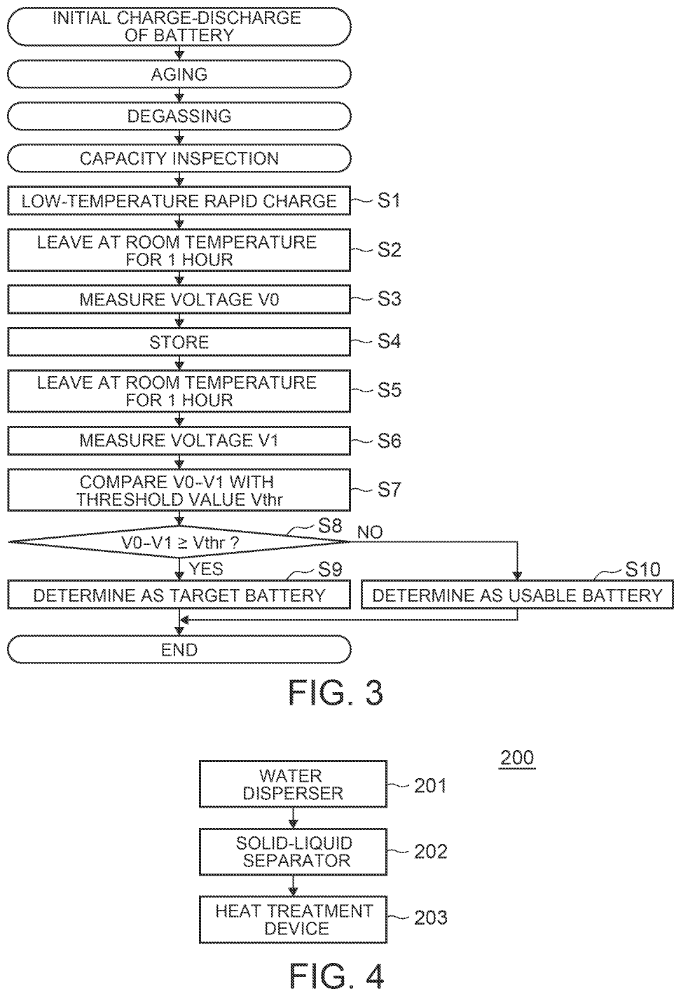

FIG. 3 is a flowchart illustrating an example of the secondary battery diagnosis method according to the embodiment. This flowchart is an example, and the order of processing or the like is not limited as long as a required processing result can be obtained.

First, initial charge-discharge is performed. This means initial charge-discharge of the secondary battery. One or more charges, one or more discharges, or both charge and discharge may be performed before aging.

The aging is desirably performed on the secondary battery in a charged state. The charged state indicates a state where lithium or lithium ions are inserted into an active material of a negative electrode. That is, it is sufficient that the secondary battery is not in a completely discharged state. A temperature and a time for aging may be set under a known condition.

Next, degassing is performed. Here, a gas generated in the aging is extracted from an electrolyte filling port. By performing the degassing, for example, a gas derived from residual moisture such as hydrogen and oxygen can be reduced. Specifically, under an argon atmosphere, the temporarily sealed battery is opened, and the pressure is reduced to discharge the above-described gas, thereby sealing the battery.

Next, the capacity inspection of the battery is performed. The capacity inspection may be performed under a known condition, and the inspection can be performed by charging to a predetermined voltage at a constant current and then discharging to a predetermined voltage under a certain temperature environment.

After the capacity inspection described above, the low-temperature rapid charge of the battery is performed (S1). In the step S1, it is preferable that, under the condition SOC 90% in a range of −25° C. or higher and 25° C. or lower, a constant current value of 0.4x or more and 1.3x or less is applied to the battery for 10 seconds or more and 30 seconds or less, where x (mA/cm) is a value obtained by dividing a current value corresponding to 10 C with respect to a cell capacity by an electrode facing area. By rapidly charging the battery at a low temperature, the growth of the foreign matter present between the electrode and the separator into a dendrite crystal can be caused to proceed. This is because, for example, when a foreign matter such as cobalt is dissolved in the electrolyte, the cobalt is hardly diffused at a low temperature, and a uniform concentration distribution of cobalt is hardly formed in the vicinity of the electrode when a voltage is applied. Furthermore, in the rapid charge, the diffusion of cobalt does not catch up with the reaction at the electrode, so that the local precipitation of cobalt easily proceeds. Thus, by performing the low-temperature rapid charge, the dendrite foreign matter is easily precipitated and grown.

The temperature in the low-temperature rapid charge is preferably −25° C. or higher. When the temperature is lower than −25° C., the ionic conductivity of the electrolytic solution is rapidly reduced, so that an overvoltage during charge is very large and charge cannot be performed. By performing rapid charge at 25° C. or lower, Co is easily precipitated in a dendrite form, so that self-discharge is easily detected. Preferably, rapid charge is performed at −25° C. or higher and 0° C. or lower. By performing the rapid charge at 0° C. or lower, when a foreign matter such as cobalt is dissolved in the electrolyte, the fluidity of the electrolyte is reduced, so that the foreign matter is hardly diffused. Therefore, when a voltage is applied, it is difficult to form a uniform concentration distribution of the foreign matter in the vicinity of the electrode, so that the local precipitation of the foreign matter can be caused to further proceed. The temperature is more preferably −20° C. or higher and −10° C. or lower.

A current applied in the low-temperature rapid charge is preferably applied, under the condition of SOC 90%, at a constant current value of 0.4x or more and 1.3x or less for 10 seconds or more and 30 seconds or less, where x (mA/cm²) is a value obtained by dividing a current value corresponding to 10C with respect to a cell capacity by an electrode facing area. When a constant current to be applied is 0.4x or more, the precipitation of the dendrite foreign matter can be promoted, and the detection of an internal short circuit in a target battery can be performed in a short time. When the value is 1.3x or less, an increase in a battery voltage due to an overvoltage can be suppressed, and the proceeding of deterioration due to the decomposition of the electrolyte can be suppressed. Since a time for applying the constant current is 10 seconds or more, the crystal growth of the foreign matter can be sufficiently promoted, and the internal short circuit in the target battery can be detected in a short time. Since the time for applying the constant current is 30 seconds or less, it is possible to prevent the battery from being exposed to a state where the voltage is high for a long time, thereby suppressing deterioration in the electrode due to a side reaction.

After the low-temperature rapid charge, the battery is left at room temperature for 1 hour to make the temperature stable (S2). Thereafter, a voltage is measured with a voltmeter, and this value is measured as a voltage V0 on the 0th day of storage of the battery (S3).

Next, the battery is stored (S4). The secondary battery is stored in a range of 45° C. or higher and 70° C. or lower for a predetermined period. By storing the battery after low-temperature rapid charge, the growth of the crystal can be caused to further proceed, and an internal short circuit can be caused by the crystal penetrating the separator. As preferable storage, under no load at a high temperature, which is storage in a state where no current flows, a cobalt foreign matter grows due to the dissolution and precipitation of cobalt, for example, which is a foreign matter contained in the outermost layer of the negative electrode. This is because the speed of the dissolution and precipitation of the foreign matter is increased at a high temperature.

When the storage temperature is 45° C. or higher, the growth of the foreign matter can be accelerated, so that an internal short circuit in a target battery can be detected in a short time. When the storage temperature is 70° C. or lower, deterioration in the electrolyte caused by the decomposition reaction of the electrolyte by the positive and negative electrodes can be suppressed. Therefore, after diagnosis, it is possible to prevent a decrease in the capacity retention ratio of a non-target battery and to detect a target battery, so that a battery with good performance can be used. A preferable range of the temperature in storage is 50° C. or higher and 60° C. or lower.

After the battery is stored for a predetermined period, the battery is left at room temperature for 1 hour, so that the temperature is stabilized (S5). Thereafter, a voltage V1 is measured in the same manner as the measurement at V0 described above (S6).

In S7, a difference V0−V1 between V0 and V1 measured in S3 and S6 is compared with a threshold value Vthr. Here, at the time of comparison with the threshold value Vthr, the absolute value of the difference between V0 and V1 may be compared with that of the threshold value Vthr. In the method of determining the threshold value Vthr, first, the active material in the battery to be diagnosed is identified. For the identification of the active material in the battery, first, the battery is completely discharged. Next, the battery is disassembled in an inert atmosphere. The positive and negative electrodes can be taken out, subjected to an appropriate pretreatment, and identified by instrument analysis. For example, the positive and negative electrodes taken out from the battery are washed using an organic solvent having the same component as that of an organic solvent contained in the electrolyte used in the battery, or a solvent such as acetone, and vacuum-dried under an environment of 25° C. to obtain positive and negative electrodes for analysis. As the composition analysis of the active material contained in the positive and negative electrodes for analysis, for example, identification analysis by X-ray fluorescence (XRF) analysis can be performed.

As other means for identifying the active material, means such as Inductively coupled plasma atomic emission spectroscopy (ICP-AES), X-ray photoelectron spectroscopy (XPS), Auger electron spectroscopy (AES), XRF analysis, secondary ion mass spectrometry (SIMS), and glow discharge-mass spectrometry (GDMS) can be used to know.

In the method of determining the threshold value Vthr, the active material contained in the battery is identified by the above-described method, and data representing the temporal change of the battery voltage in the battery using the active material is then read. The threshold value Vthr is determined with reference to the battery voltage dropped until the secondary battery in the data is to be replaced. The set threshold value Vthr can be changed depending on the purpose of use of the secondary battery to be diagnosed and the predetermined period of storage described above. When the secondary battery diagnosis method according to the present embodiment is implemented as a device, the data of the battery voltage may be obtained by a storage unit included in the device including data in advance or by downloading the data from a cloud or the like each time.

In S8, whether the battery to be diagnosed is usable or the target battery is determined based on the magnitude of the voltage difference V0−V1 and the threshold value Vthr described above. When the voltage difference V0−V1 is equal to or greater than the threshold value Vthr (YES in S8), it is determined that the diagnosed battery is the target battery in S9. Meanwhile, when the voltage difference V0−V1 is smaller than the threshold value Vthr (NO in S8), the battery is determined to be usable in S10.

After the battery is determined in S9 or S10, the diagnosis result is output, and the process ends.

Here, when it is determined in S9 that the battery is the target battery, for example, a niobium-titanium oxide can be recovered from an electrode containing the niobium-titanium oxide by a recycling system as illustrated in FIG. 4. FIG. 4 specifically illustrates an example of a recycling system for recovering a niobium-titanium oxide from a battery. A recycling system 200 includes a water disperser 201, a solid-liquid separator 202 disposed downstream of the water disperser 201, and a heat treatment device 203 disposed downstream of the solid-liquid separator 202. An object to be treated is conveyed by a conveyor and a slurry pump (not illustrated) or the like in the order of the water disperser 201, the solid-liquid separator 202, and the heat treatment device 203. Therefore, the recycling system 200 may include a carrier that conveys the object to be treated.

The water disperser 201 disperses an electrode containing a niobium-titanium oxide (Hereinafter, referred to as a TNO electrode) in water. When the TNO electrode is immersed in water, the TNO electrode can be divided into a current collector and other members, and dispersed in water. This water dispersion is likely to occur when the TNO electrode contains a water-soluble or water-dispersible binder. The niobium-titanium oxide is hardly deteriorated when brought into contact with water. Therefore, by dispersing the TNO electrode in water, the TNO electrode can be disassembled without damaging the niobium-titanium oxide. The water disperser 201 is not particularly limited as long as it includes a container capable of storing water for dispersing the TNO electrode. Examples thereof include a mixing tank equipped with a stirring blade. To facilitate the disassembly of the TNO electrode, the water disperser 201 may include a pulverizer for pulverizing the TNO electrode.

A slurry in which a TNO electrode is dispersed in water is supplied from the water disperser 201 to the solid-liquid separator 202. The solid-liquid separator 202 solid-liquid separates the current collector and the niobium-titanium oxide from the slurry in which a TNO electrode is dispersed in water. The niobium-titanium oxide has a higher density than those of other materials constituting the electrode, and thus is suitable for separation using a density difference. A current collecting foil composed of aluminum or the like is larger in size than that of the niobium-titanium oxide, and therefore the current collecting foil can also be separated using the size. Examples of the solid-liquid separator 202 include a sedimentation separator, a cyclone, and a sieve.

The heat treatment device 203 performs heat treatment on the niobium-titanium oxide separated by the solid-liquid separator 202. Examples of the heat treatment device include a furnace and a rotary kiln.

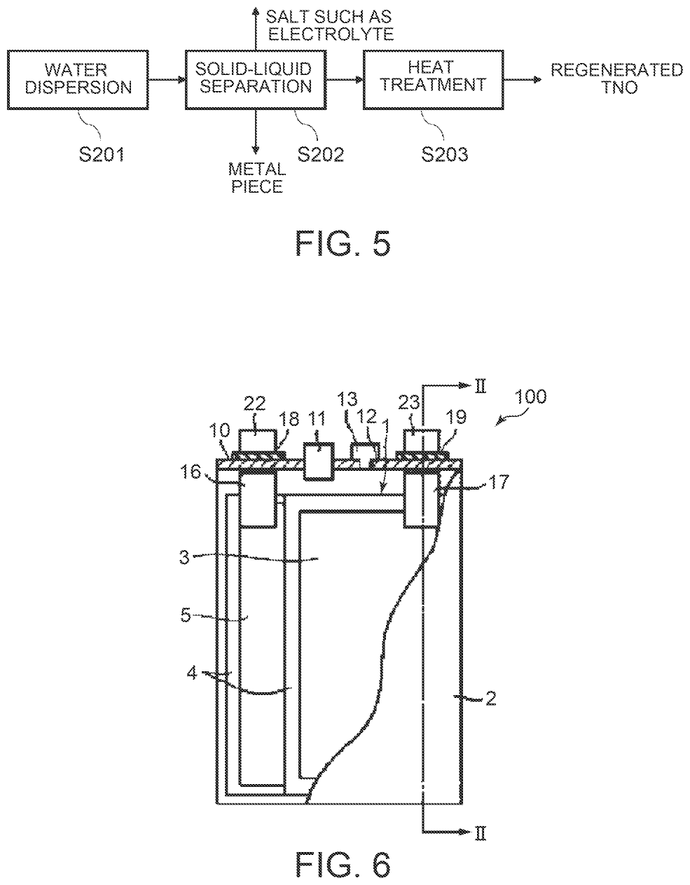

A recycling method using the recycling system 200 described above will be described with reference to FIG. 5. A recycling method illustrated in FIG. 5 includes a water dispersion step S201, a solid-liquid separation step S202, and a heat treatment step S203.

### (Water Dispersion Step S201)

A TNO electrode is fed into the water disperser 201 and immersed in water in the water disperser 201. As a result, the TNO electrode is dispersed in water and divided into a metal piece such as a current collector and an electrode material containing a niobium-titanium oxide. The TNO electrode is sent in a state where the TNO electrode is dispersed in water to the next step S202.

### (Solid-Liquid Separation Step S202)

For example, the metal piece is removed from the slurry in which the TNO electrode is dispersed in water using the sedimentation separator. According to the sedimentation separation, it is also possible to remove materials (for example, a carbon material) having a density lower than that of the niobium-titanium oxide. After removal, the slurry is sieved to remove a foreign matter. The cyclone then separates the niobium-titanium oxide from the slurry. The separated niobium-titanium oxide is washed with water to remove remaining ions (for example, a salt such as an electrolyte (a salt containing P or F)) and a water-soluble material (for example, a water-soluble binder). The washed niobium-titanium oxide is conveyed to the next step S203.

### (Heat Treatment Step S203)

The washed niobium-titanium oxide is subjected to a heat treatment. As a result, the capacity of the niobium-titanium oxide can be recovered, so that the niobium-titanium oxide can be reused. When the carbon material adheres to the surfaces of niobium-titanium oxide particles, the carbon material can be removed by the heat treatment. The heat treatment can be performed at a temperature of 600° C. or higher and 1200° C. or lower for 24 hours or less in the air. A more preferable range of the treatment time is 1 hour or more and 24 hours or less. When the treatment temperature is low or the treatment time is short, it is difficult to sufficiently recover the capacity of the niobium-titanium oxide. Meanwhile, when the treatment temperature is high or the treatment time is long, there is a possibility that the niobium-titanium oxide causes excessive grain growth, resulting in deterioration in characteristics.

In order to adjust the grain size of the niobium-titanium oxide subjected to the heat treatment, the niobium-titanium oxide may be pulverized.

According to the recycling system and the recycling method described above, the reusable niobium-titanium oxide can be recovered from the electrode. In the above description, for example, by adopting the method of recovering the lithium-titanium oxide from the electrode containing the lithium-titanium oxide, it is also possible to recycle the battery containing the lithium-titanium oxide.

The secondary battery in which the secondary battery diagnosis method of the present embodiment is used is, for example, a secondary battery having the following configuration.

### (Electrode)

An electrode can include a current collector and an active material-containing layer. The active material-containing layer may be laminated or formed on one surface or both surfaces of the current collector. The active material-containing layer can contain an active material, and optionally a conductive agent and a binder.

In a negative electrode, an active material having an average operating potential of 1.0 VvsLi/Li⁺ or more occupies 50% by weight or more of the total weight of a negative electrode active material-containing layer. That is, 50% by weight or more of the negative electrode active material-containing layer is occupied by an active material having an average operating potential based on Li ion is 1.0 V or more. In other words, 50% by weight or more of the negative electrode active material-containing layer is occupied by an active material having an average operating potential during insertion and desorption of Li ions is 1.0 V or more. 1.0 VvsLi/Li⁺ may be referred to as 1.0 V (vs. Li/Li⁺). The total weight ratio of Mn, Fe, Co, and Ni contained in a material constituting the negative electrode is 50 ppm or more with respect to an active material contained in the negative electrode.

A negative electrode active material contains a niobium-titanium oxide. The niobium-titanium oxide contains, for example, a compound represented by Li_{χ}TiMe_{α}Nb_{2±β}O_{7±σ}, and satisfying 0≤χ≤5, 0≤α0.3, 0≤β≤0.3, and 0≤σ≤0.3, wherein Me is 1 or more selected from the group consisting of Fe, V, Mo, and Ta.

A sodium-niobium-titanium oxide contains, for example, an orthorhombic Na-containing niobium-titanium oxide represented by the general formula Li_{2+d}Na₂₋ₑMe1_{f}Ti_{6-g-h}Nb_{g}Me2ₕO_{14+δ}, and contains an orthorhombic Na-containing niobium-titanium oxide satisfying 0≤d≤4, 0≤e<2, 0≤f<2, 0<g<6, 0≤h<3, g+h<6, and −0.5≤δ≤0.5, wherein Me1 contains one or more selected from Cs, K, Sr, Ba, and Ca, and Me2 contains one or more selected from Zr, Sn, V, Ta, Mo, W, Fe, Co, Mn, and Al.

As the negative electrode active material, a titanium oxide having an anatase structure, a titanium oxide having a monoclinic structure, a lithium-titanium oxide having a spinel structure, a niobium-titanium oxide, or a mixture thereof can be further used. Meanwhile, when the titanium oxide having an anatase structure, the titanium oxide having a monoclinic structure, or the lithium-titanium oxide having a spinel structure is used as the negative electrode active material, for example, a high electromotive force can be obtained by combining with a positive electrode that uses a lithium-manganese composite oxide as a positive electrode active material as a counter electrode of an electrode included in an electrode structure. On the other hand, by using a niobium-titanium oxide, a high capacity can be exhibited.

The negative electrode active material can further contain a lithium-titanium oxide. Examples of the lithium-titanium oxide include a lithium-titanium oxide having a spinel structure (for example, the general formula Li₄₊ₓTi₅O₁₂ (x is −1≤x≤3)), a lithium-titanium oxide having a ramsdellite structure (for example, Li₂₊ₓTi₃O₇ (−1≤x≤3)), Li₁₊ₓTi₂O4 (0≤x≤1), Li_{1.1+x}Ti_{1.8}O₄ (0≤x≤1), Li_{1.07+x}Ti_{1.86}O₄ (0≤x≤1), and LiₓTiO₂ (0<x≤1).

A negative electrode current collector is preferably made of, for example, copper, nickel, stainless steel or aluminum, or an aluminum alloy containing one or more elements selected from the group consisting of Mg, Ti, Zn, Mn, Fe, Cu, and Si.

Examples of a compound that can be used as a positive electrode active material include a lithium-manganese composite oxide, a lithium-nickel composite oxide, a lithium-cobalt-aluminum composite oxide, a lithium-nickel-cobalt-manganese composite oxide, a spinel type lithium-manganese-nickel composite oxide, a lithium-manganese-cobalt composite oxide, a lithium-iron oxide, a lithium fluorinated iron sulfate, and a phosphate compound having an olivine crystal structure (for example, a compound represented by LiₖFePO₄ and satisfying 0<k≤1, and a compound represented by LiₖMnPO₄ and satisfying 0<k≤1). The phosphate compound having an olivine crystal structure is excellent in thermal stability.

Examples of a compound capable of obtaining a high positive electrode potential include lithium-manganese composite oxides such as a compound represented by, for example, LiₖMn₂O₄ having a spinel structure and satisfying 0<k≤1 and a compound represented by LiₖMnO₂ and satisfying 0<k≤1; lithium-nickel-aluminum composite oxides such as a compound represented by, for example, LiₖNi₁₋ᵢAlᵢO₂ and satisfying 0<k≤1 and 0<i<1; lithium-cobalt composite oxides such as a compound represented by, for example, LiₖCoO₂ and satisfying 0<k≤1; lithium-nickel-cobalt composite oxides such as a compound represented by, for example, LiₖNi₁₋ᵢ₋ₜCoᵢMnₜO₂ and satisfying 0<k≤1, 0<i<1, and 0≤t<1; lithium-manganese-cobalt composite oxides such as a compound represented by, for example, LiₖMnᵢCo₁₋ᵢO₂ and satisfying 0<k≤1 and 0≤y≤1; spinel-type lithium-manganese-nickel composite oxides such as a compound represented by, for example, LiₖMn_{2-κ}Ni_{κ}O₄ and satisfying 0<k≤1 and 0<κ<2; lithium phosphorus oxides having an olivine structure such as a compound represented by, for example, LiₖFePO₄ and satisfying 0<k≤1, a compound represented by LiₖFe_{1-y}Mn_{y}PO₄ and satisfying 0<k≤1 and 0≤y≤1, and a compound represented by LiₖCoPO₄ and satisfying 0<k≤1; and fluorinated iron sulfates (for example, a compound represented by LiₖFeSO₄F and satisfying 0<k≤1).

The positive electrode active material preferably contains one or more selected from the group consisting of a lithium-cobalt composite oxide, a lithium-manganese composite oxide, and a lithium-phosphorus oxide having an olivine structure. The operating potentials of these compounds are 3.5 V (vs. Li/Li⁺) or more and 4.2 V (vs. Li/Li⁺) or less. That is, the operating potentials of these compounds as active materials are relatively high. By using these compounds in combination with the above-described negative electrode active materials such as spinel-type lithium titanate and an anatase-type titanium oxide, a high battery voltage can be obtained.

A positive electrode current collector contains, for example, metals such as stainless steel, aluminum (Al), and titanium (Ti). The positive electrode current collector has, for example, a foil shape, a porous body shape, or a mesh shape. In order to prevent corrosion due to a reaction between the positive electrode current collector and the aqueous electrolyte, the surface of the positive electrode current collector may be coated with a different element.

The conductive agent is blended as necessary in order to enhance current collecting performance and suppress contact resistance between the active material (first active material) and a current collecting layer. Examples of the conductive agent include carbonaceous substances such as acetylene black, Ketjen black, graphite, and coke. The conductive agent may be used singly or in combination of two or more kinds thereof.

The binder has an action of binding the active material and the conductive agent. As the binder, for example, at least one selected from the group consisting of cellulose-based polymers such as polytetrafluoroethylene (PTFE), polyvinylidene fluoride (PVdF), and carboxymethyl cellulose (CMC), fluorine-based rubber, styrene butadiene rubber, an acrylic resin or a copolymer thereof, polyacrylic acid, and polyacrylonitrile can be used, but the binder is not limited thereto. The binder may be used singly or in combination of two or more kinds thereof.

### (Electrolyte)

As an electrolyte, for example, an aqueous electrolyte or a non-aqueous electrolyte or the like can be used. As the electrolyte, a liquid electrolyte or a gel electrolyte can be used. The non-aqueous electrolyte is prepared, for example, by dissolving an electrolyte salt such as a lithium salt in an organic solvent. The aqueous electrolyte is prepared, for example, by dissolving an electrolyte salt such as a lithium salt in an aqueous solvent. Examples of the electrolyte salt include lithium salts such as lithium perchlorate (LiClO₄), lithium hexafluorophosphate (LiPF₆), lithium tetrafluoroborate (LiBF₄), lithium arsenic hexafluoride (LiAsF₆), lithium trifluoromethanesulfonate (LiCF₃SO₃), and lithium bistrifluoromethylsulfonylimide (LiN(CF₃SO₂)₂)

### (Separator)

A separator is not particularly limited as long as it can electrically insulate the positive electrode and the negative electrode from each other. For example, the separator is formed of a porous film containing polyethylene (PE), polypropylene (PP), cellulose, or polyvinylidene fluoride (PVdF), or a synthetic resin nonwoven fabric.

### (Exterior Member)

As an exterior member, for example, a container composed of a laminate film or a metal exterior can is capable of being used.

As the laminate film, a multilayer film including a plurality of resin layers and a metal layer interposed between the resin layers is used. The resin layer contains polymer materials such as, for example, polypropylene (PP), polyethylene (PE), nylon, and polyethylene terephthalate (PET). The metal layer is preferably composed of an aluminum foil or an aluminum alloy foil for weight reduction. The laminate film can be formed into the shape of the exterior member by performing sealing by thermal fusion.

The exterior can is made of, for example, aluminum or an aluminum alloy. The aluminum alloy preferably contains elements such as magnesium, zinc, and silicon. When the aluminum alloy contains iron, copper, nickel, and transition metal such as chromium, the content thereof is preferably 1% by mass or less.

The shape of the exterior member is not particularly limited. The shape of the exterior member may be, for example, a flat shape (thin shape), a square shape, a cylindrical shape, a coin shape, or a button shape or the like. The exterior member can be appropriately selected according to the size of the battery and the application of the battery.

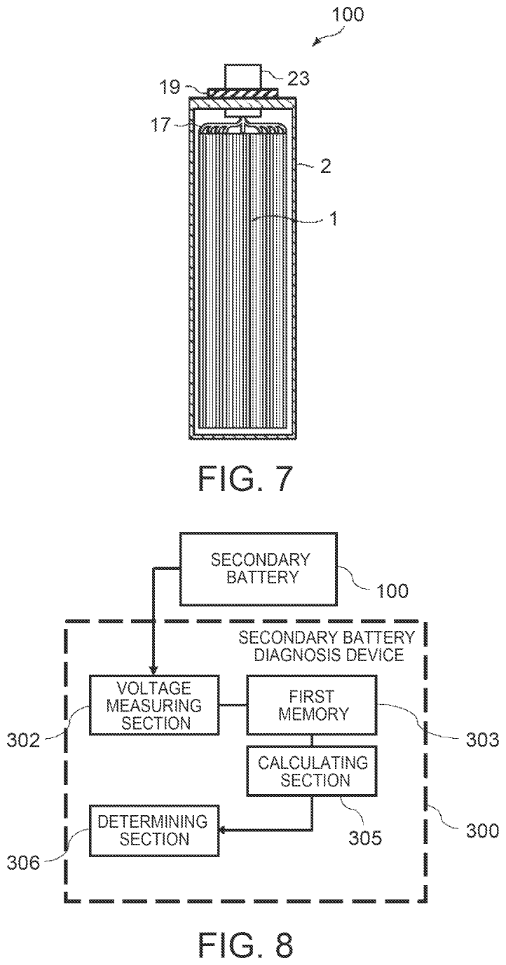

The secondary battery in which the secondary battery diagnosis method of the present embodiment is used is, for example, a secondary battery illustrated in FIGS. 6 and 7. FIG. 6 is a cross-sectional view schematically illustrating an example of the secondary battery in which the secondary battery diagnosis method of the present embodiment is used. FIG. 7 is a cross-sectional view of the secondary battery illustrated in FIG. 6 and taken along line II-II.

An electrode group 1 is housed in a rectangular cylindrical metal container 2. The electrode group 1 has, for example, a structure in which a plurality of positive electrodes 5, negative electrodes 3, and separators 4 are laminated in the order of the positive electrode 5, the separator 4, the negative electrode 3, and the separator 4. Alternatively, the electrode group 1 may have a structure in which the positive electrode 5 and the negative electrode 3 are spirally wound so as to have a flat shape with the separator 4 interposed therebetween. In any structure of the electrode group 1, it is desirable to have a structure in which the separator 4 is disposed on the outermost layer of the electrode group 1 in order to avoid contact between the electrode and the metal container 2. The electrode group 1 holds an electrolyte (not illustrated).

As illustrated in FIG. 7, belt-shaped negative electrode tabs 17 are electrically connected to a plurality of places of the end portion of the negative electrode 3 located on the end surface of the electrode group 1. Although not illustrated, belt-shaped positive electrode tabs 16 are electrically connected to a plurality of portions of the end portion of the positive electrode 5 located on the end surface. The plurality of negative electrode tabs 17 are electrically connected to a negative electrode lead 23 in a bundled state. The negative electrode tab 17 (negative electrode internal terminal) and the negative electrode lead 23 (negative electrode external terminal) constitute a negative electrode terminal. The positive electrode tabs 16 are connected to a positive electrode lead 22 in a bundled state. The positive electrode tab 16 (positive electrode internal terminal) and the positive electrode lead 22 (positive electrode external terminal) constitute a positive electrode terminal.

A metal sealing plate 10 is fixed to the opening of a metal container 2 by welding or the like. The positive electrode lead 22 and the negative electrode lead 23 are drawn to the outside from extraction holes provided in the sealing plate 10. In order to avoid a short circuit due to contact with the positive electrode lead 22 and the negative electrode lead 23, a positive electrode gasket 18 and a negative electrode gasket 19 are disposed on the inner peripheral surface of each extraction hole of the sealing plate 10. By disposing the positive electrode gasket 18 and the negative electrode gasket 19, the airtightness of the rectangular secondary battery can be maintained.

The sealing plate 10 is provided with a controlling valve 11 (safety valve). When an internal pressure in a battery cell increases due to a gas generated by the electrolysis of the aqueous solvent, the generated gas can be diffused to the outside from the controlling valve 11. As the controlling valve 11, for example, a return type valve that operates when the internal pressure becomes higher than a set value and functions as a sealing plug when the internal pressure decreases can be used. Alternatively, a non-return type control valve whose function as a sealing plug is not restored once operated may be used. In FIG. 6, the controlling valve 11 is disposed at the center of the sealing plate 10, but the controlling valve 11 may be positioned at the end portion of the sealing plate 10. The controlling valve 11 may be omitted.

The sealing plate 10 is provided with a liquid injection port 12. The electrolyte can be injected through the liquid injection port 12. The liquid injection port 12 is closed by a sealing plug 13 after the electrolyte is injected therein. The liquid injection port 12 and the sealing plug 13 may be omitted.

As described above, the secondary battery diagnosis method according to the first embodiment provides a secondary battery diagnosis method including: rapidly charging a secondary battery at a low temperature; storing the secondary battery in a range of 45° C. or higher and 70° C. or lower for a predetermined period; and determining a degree of voltage drop of the secondary battery before and after storing the secondary battery. The secondary battery includes a negative electrode in which an active material having an average operating potential of 1.0 VvsLi/Li⁺or more occupies 50% by weight or more of a total weight of a negative electrode active material-containing layer. This makes it possible to detect a battery whose battery voltage may be reduced in a short time.

### Second Embodiment

In a second embodiment, a secondary battery diagnosis device will be described. The secondary battery diagnosis device according to the second embodiment includes: a secondary battery rapidly charged at a low temperature; a voltage measuring section that measures a voltage V0 of the secondary battery before start of the storage and a voltage V1 of the secondary battery after the storage for a predetermined period, for the secondary battery stored for a predetermined period in a range of 45° C. or higher and 70° C. or lower; a first memory that memorizes the voltage V0 and the voltage V1; a calculating section that calculates a difference between the voltage V0 and the voltage V1; and a determining section that determines that the secondary battery is a target battery when the value calculated by the calculating section is equal to or greater than a threshold value, wherein the secondary battery includes a negative electrode in which an active material having an average operating potential of 1.0 VvsLi/Li⁺or more occupies 50% by weight or more of a total weight of a negative electrode active material-containing layer.

FIG. 8 is a block diagram illustrating an example of the schematic configuration of the secondary battery diagnosis device according to the present embodiment. The secondary battery diagnosis device according to the present embodiment is indicated by a broken line in FIG. 8. A secondary battery diagnosis device 300 includes a voltage measuring section 302, a first memory 303, a calculating section 305, and a determining section 306. The voltage measuring section 302 is, for example, a voltmeter.

Whether a secondary battery 100 is a cell to be replaced is diagnosed by the secondary battery diagnosis device 300. The term “secondary battery” includes an assembled battery using a secondary battery, a battery pack, a battery module, and a unit battery.

The secondary battery 100 may be, for example, a secondary battery mounted on a device such as a mobile phone, a notebook computer, an electric bicycle, a hybrid car using both electricity and gasoline, or a drone. For example, a stationary storage battery installed for each of plants such as a private house, a building, or a factory may be used. The secondary battery may be a storage battery linked to a power generation system or a secondary battery interlinked systemwise.

After the secondary battery 100 is rapidly charged at a low temperature, the secondary battery 100 is stored in the range of 45° C. or higher and 70° C. or lower for a predetermined period, and the voltage measuring section 302 measures the voltage V0 of the secondary battery 100 before the start of the storage and the voltage V1 of the secondary battery 100 after the storage for the predetermined period.

The first memory 303 memorizes the voltage V0 and the voltage V1 measured by the voltage measuring section 302 described above. The first memory 303 may memory at least the voltage V0, and the voltage measuring section 302 may measure the voltage V1 after the secondary battery 100 is stored for a predetermined period. Then, the first memory 303 may read the voltage V0 memorized in the first memory 303, and the calculating section 305 may calculate the difference between the voltage V0 and the voltage V1.

The first memory 303 may memorize a threshold value Vthr to be compared with the difference between the voltage V0 and the voltage V1. The threshold value Vthr can be changed depending on the purpose of use of the secondary battery 100 to be diagnosed.

The calculating section 305 calculates the difference between the voltage V0 and the voltage V1 with reference to at least the voltage V0 memorized in the first memory unit 303. The calculating section 305 may calculate a difference between the difference between the voltage V0 and the voltage V1 and the threshold value Vthr to obtain which value is greater. In that case, for example, the calculating section 305 can calculate whether or not (V0−V1)−Vthr obtained by subtracting the threshold value Vthr from the difference between the voltage V0 and the voltage V1 is 0 or more.

The determining section 306 determines whether the secondary battery 100 is a target battery based on the value of V0−V1 and the threshold value Vthr.

The secondary battery diagnosis device 300 may further include an acquiring section (not illustrated). At that time, for example, the voltage measuring section 302 and the first memory unit 303 may not be included in the secondary battery diagnosis device 300. That is, the secondary battery diagnosis device 300 may not measure the voltage V0 of the secondary battery 100 before the start of the storage and the voltage V1 of the secondary battery 100 after the storage for a predetermined period, and may not memorize the voltages V0 and V1. After the voltages V0 and V1 are measured, the acquiring section may acquire data of the voltages V0 and V1, and the calculating section 305 may calculate the difference between the voltage V0 and the voltage V1.

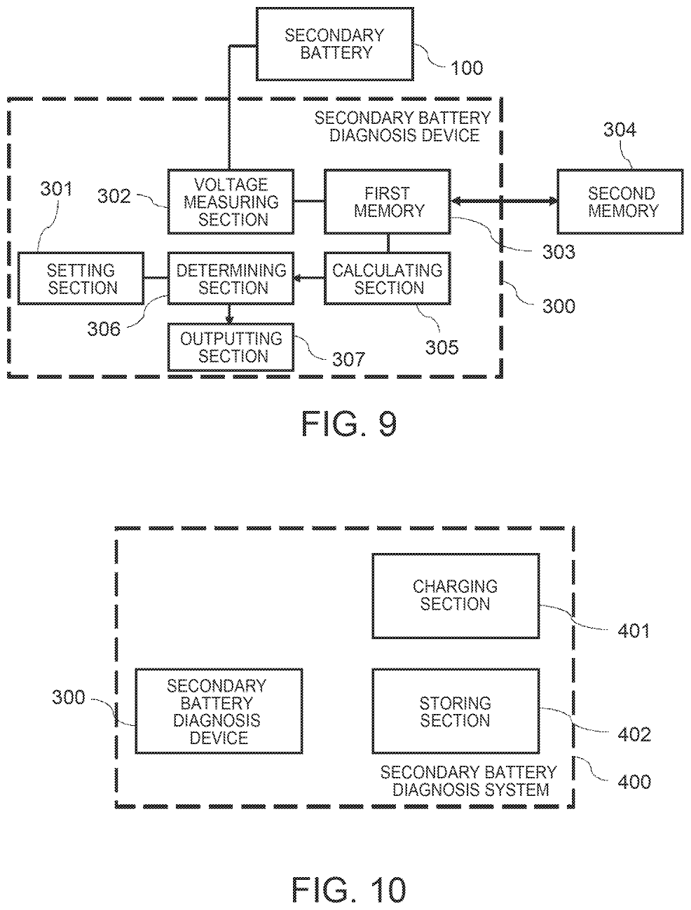

The secondary battery diagnosis device 300 can further include a setting section and an outputting section. FIG. 9 is a block diagram illustrating another example of the schematic configuration of the secondary battery diagnosis device according to the present embodiment.

A setting section 301 sets the threshold value Vthr. The threshold value Vthr can be changed depending on the purpose of use of the secondary battery 100 to be diagnosed or a predetermined period of time for storing the secondary battery 100. For example, the setting section 301 may be attached to the determining section 306, and the determining section 306 may determine whether or not the secondary battery 100 is a target battery with reference to the threshold value Vthr set by the setting section 301.

The first memory 303 may memory not only the voltage value when the secondary battery is stored as described above but also the threshold value Vthr set by the setting section 301. The first memory 303 can download and memory, from a second memory 304, data indicating a temporal change in the battery voltage in the battery containing each active material. Alternatively, the first memory unit 303 may memory data indicating a temporal change of the battery voltage in advance.

An outputting section 307 outputs a determination result as to whether the secondary battery 100 is a target battery as the diagnosis result. The outputting method of the outputting section 307 is not particularly limited. The outputting section 307 may be a file, an email, an image, sound, or light. For example, the secondary battery diagnosis device 300 may be electrically connected to a display or a speaker or the like via the outputting section 307, and a processing result may be output to another device. The outputting method and contents may be determined in advance or may be selected each time.

The configuration of the secondary battery diagnosis device 300 described above is an example, and is not limited to the above configuration. For example, some components of the secondary battery diagnosis device 300 may be separated from the secondary battery diagnosis device 300 with the components used as an external device so that necessary data can be transmitted and received by communication or an electric signal.

As described above, the secondary battery diagnosis device according to the second embodiment includes: a secondary battery rapidly charged at a low temperature; a voltage measuring section that measures a voltage V0 of the secondary battery before start of storage and a voltage V1 of the secondary battery after the storage for a predetermined period, for the secondary battery stored for a predetermined period in a range of 45° C. or higher and 70° C. or lower; a first memory that memorizes the voltage V0 and the voltage V1; a calculating section that calculates a difference between the voltage V0 and the voltage V1; and a determining section that determines that the secondary battery is a target battery when the value calculated by the calculating section is equal to or greater than a threshold value, wherein the secondary battery includes a negative electrode in which an active material having an average operating potential of 1.0 VvsLi/Li⁺ or more occupies 50% by weight or more of a total weight of a negative electrode active material-containing layer. This makes it possible to detect a battery whose battery voltage may be reduced in a short time.

### Third Embodiment

In a third embodiment, a secondary battery diagnosis system will be described. The secondary battery diagnosis system according to the third embodiment is a secondary battery diagnosis system including: a charging section configured to rapidly charge a secondary battery at a low temperature; a storing section that stores the secondary battery after being rapidly charged at a low temperature; and the secondary battery diagnosis device according to the second embodiment.

These devices including tools used for battery diagnosis are electrically and physically connected to each other to form a secondary battery diagnosis system. One tool used for battery diagnosis in one device may be provided, or a plurality of tools may be provided.

FIG. 10 is a block diagram schematically illustrating the secondary battery diagnosis system according to the present embodiment. A secondary battery diagnosis system 400 includes the secondary battery diagnosis device 300 described in the second embodiment, a charging section 401, and a storing section 402.

The charging section 401 rapidly charges the secondary battery at a low temperature. A method for low-temperature rapid charge is the same as the method described above in the first embodiment, and thus is omitted. The charging section 401 is, for example, a charger.

The storing section 402 stores the secondary battery after the secondary battery is rapidly charged at a low temperature in the charging section 401. The storage method is the same as the method described above in the first embodiment, and thus is omitted. The storing unit 402 is, for example, a storing device. In the second embodiment, the secondary battery diagnosis device 300 includes the voltage measuring section, but for example, the voltage measuring section may be included in the charging section.

The secondary battery diagnosis system 400 may further include a controlling section (controller) (not illustrated) For example, in the low-temperature rapid charge performed by the charging section 401, the controlling section may set a constant current to be applied, a temperature, and a time for applying the constant current, and the like to control the low-temperature rapid charge. Similarly, in the storage performed by the storing section 402, the controlling section may instruct the voltage measuring section to set the storage temperature and measure the voltage V0 on the 0th day of the storage and the voltage V1 after the storage for a predetermined period.

In the present embodiment, the secondary battery 100 and the secondary battery diagnosis system 400 are separately described, but the secondary battery diagnosis device 300 realized by a control circuit or the like may be provided in the secondary battery 100 to form one secondary battery 100 (power storage device) provided with the secondary battery diagnosis device 300.

### EXAMPLES

Examples will be described below, but the embodiments are not limited to Examples described below.

### Example 1

### <Production of Negative Electrode>

Nb₂O₅ particles and TiO₂ particles were mixed in a molar ratio of 1:1 using a dry bead mill. The obtained powder was placed in an alumina crucible and heated at a temperature of 800° C. for 10 hours. Thereafter, the powder was pulverized and mixed, and then pre-fired again at a temperature of 800° C. for 10 hours to obtain precursor particles. Furthermore, the obtained precursor particles were main-fired at 1100° C. for 5 hours to obtain a Nb₂TiO₇ powder.

The Nb₂TiO₇ (TNO) powder obtained above was used as a negative electrode active material, and acetylene black AB, multi-walled carbon nanotube MWCNT as a conductive agent, a carboxymethyl cellulose (CMC) sodium salt powder as a thickener, and a styrene-butadiene rubber (SBR) dispersion liquid as a binder were prepared. The multi-walled carbon nanotube MWCNT to be used contained 5000 ppm of impurity Co. These materials were mixed in the following order at a mass ratio of TNO:AB:MWCNT:CMC:SBR=100:5:5:2:2 while pure water as a solvent was stirred to prepare a slurry. A carboxymethylcellulose sodium salt was dissolved in pure water, and then SBR was further mixed to obtain a dispersion liquid. AB and MWCNT were dispersed in this dispersion liquid, and finally, a TNO powder was dispersed, followed by stirring to obtain a slurry. This slurry was applied to both surfaces of a current collector composed of an aluminum foil having a thickness of 12 μm. Thereafter, the slurry coating film was dried and pressed to form a negative electrode active material-containing layer. Thereafter, the current collector was cut out so that the surface of the negative electrode active material-containing layer had a rectangular contour. However, a portion of the current collector where the active material-containing layer was not formed was left on one side of the rectangle to form a current collecting tab.

### <Production of Positive Electrode>

3 g of LiNi_{0.8}Co_{0.1}Mn_{0.1}O₂ was prepared as a positive electrode active material. Acetylene black (AB) as a conductive agent and a PVdF dispersion liquid (N-methyl-2-pyrrolidone (NMP) having a solid content rate of 8%) as a binder (binder resin) were prepared. These materials were added to NMP at a mass ratio of NCM:AB:PVdF=20:1:1, followed by mixing to prepare an active material-containing slurry. This slurry was applied to both surfaces of a current collector composed of an aluminum foil having a thickness of 12 μm. Thereafter, the slurry coating film was dried and pressed to form a positive electrode active material-containing layer. Thereafter, the current collector was cut out so that the surface of the positive electrode active material-containing layer had a rectangular contour. However, a portion of the current collector where the active material-containing layer was not formed was left on one side of the rectangle to form a current collecting tab.

### <Production of Electrode Group>

A cellulose separator having a thickness of 15 μm was prepared. A coil body was obtained, which had a structure in which a separator was interposed between the above-described positive electrode and negative electrode, and the positive electrode, the negative electrode, and the separator were wound in a spiral shape so as to have a flat shape.

### <Preparation of Electrolyte>

Propylene carbonate (PC) and diethyl carbonate (DEC) were mixed at a volume ratio of PC:DEC=1:2 to obtain a mixed solvent. 1.0 M of lithium hexafluorophosphate (LiPF6) was dissolved in the mixed solvent to prepare a liquid nonaqueous electrolyte.

### <Assembly of Secondary Battery>

The electrode group was housed in a pack of a laminate film composed of an aluminum foil and polypropylene layers formed on both surfaces of the aluminum foil. Thereafter, the liquid nonaqueous electrolyte was injected into the laminate film pack in which the electrode group was housed. The laminate film pack was completely sealed by heat sealing to produce a battery.

### <Low-Temperature Rapid Charge of Secondary Battery>

After the secondary battery was assembled, the battery of each Example was initially charged, and then subjected to aging, degassing, and capacity inspection. Each condition can be set under a known condition. Thereafter, under the condition SOC 90% at −20° C., a current value of 1.0x was applied to the battery at a constant current for 10 seconds, where x (mA/cm²) was a value obtained by dividing a current value corresponding to 10 C by an electrode facing area.

### <Storage of Secondary Battery>

After the low-temperature rapid charge of the secondary battery was completed, the secondary battery was left at 25° C. for 1 hour to stabilize the temperature. Thereafter, a voltage V0 on the 0th day of storage was measured with a voltmeter. Next, the cell was transferred to a thermostatic bath at 60° C. and left for y days without applying a current. Thereafter, the cell was left at room temperature for 1 hour, and then a voltage Vy on the yth day of storage was measured. V0−Vy is calculated, and a day on which this difference exceeds the threshold value is illustrated in Table 1 as a target battery detection day. The threshold value was set to 0.050 V.

In Example 1, the voltage difference did not exceed the threshold value in less than ten days, and therefore the target battery was not detected, and the voltage difference became equal to or greater than the threshold value for the first time on the tenth day.

### <Constant Current Charge-Discharge Test>

For the secondary battery produced in each Example, the test was started after the above-described storage. Both charge and discharge were performed at a 0.5 C rate. At the time of charge, an earlier one of until a current value reached 0.25 C and until a charge time reached 130 minutes was set as a termination condition. The termination condition was set to 130 minutes at the time of discharge.

### <Measurement of Capacity Retention Ratio>

After the constant current charge-discharge test described above was performed, the battery was charged to SOC 100% at a constant current at a 1 C rate (600 mA) in a temperature environment of 25° C. After a quiescent time of 10 minutes, the battery was discharged to SOC 0% at a constant current of 1 C rate (600 mA). This charge-discharge was performed once as one cycle of charge-discharge. A discharge capacity at the 5th cycle was set to 100%, the cycle was repeated, and the retention rate of a discharge capacity (mAh) at the 200th cycle was defined as a capacity retention rate. By evaluating the capacity retention rate, it is possible to confirm whether the performance of the battery is deteriorated after the secondary battery diagnosis method is performed.

### Example 2

A procedure in Example 2 was similar to that in Example 1 except that a temperature at the time of low-temperature rapid charge was set to 0° C. In Example 2, when the voltage difference was calculated after storage, the voltage difference became equal to or greater than a threshold value for the first time on the tenth day, and a target battery was detected.

### Example 3

A procedure in Example 3 was similar to that in Example 1 except that a temperature at the time of low-temperature rapid charge was set to 25° C. In Example 3, when the voltage difference was calculated after storage, the voltage difference became equal to or greater than a threshold value for the first time on the tenth day, and a target battery was detected.

### Example 4

A procedure in Example 4 was similar to that in Example 1 except that a temperature at the time of storage was set to 45° C. In Example 4, when the voltage difference was calculated after storage, the voltage difference became equal to or greater than a threshold value for the first time on the tenth day, and a target battery was detected.

### Example 5

A procedure was similar to that in Example 1 except that a temperature at the time of storage was 70° C. In Example 5, when the voltage difference was calculated after storage, the voltage difference became equal to or greater than a threshold value for the first time on the tenth day, and a target battery was detected.

### Example 6

A Li₄Ti₅O₁₂ (TLO) powder as a negative electrode active material was added to NMP at a mass ratio of TLO:AB:PVdF=20:1:1, followed by mixing to prepare an active material-containing slurry. The subsequent steps were performed in the same manner as in Example 1 except that a current value applied at the time of low-temperature rapid charge was set to 0.5x. In Example 6, when the voltage difference was calculated after storage, the voltage difference became equal to or greater than a threshold value for the first time on the tenth day, and a target battery was detected.

### Comparative Example 1

A procedure in Comparative Example 1 was similar to that in Example 1 except that a temperature at the time of storage was set to 80° C. In Comparative Example 10, when the voltage difference was calculated after storage, the voltage difference became equal to or greater than a threshold value for the first time on the fifth day, and a target battery was detected.

### Comparative Example 2

A procedure in Comparative Example 2 was similar to that in Example 1 except that a temperature at the time of storage was set to 25° C. In Comparative Example 2, when the voltage difference was calculated after storage, the voltage difference became equal to or greater than a threshold value for the first time on the 45th day, and a target battery was detected.

### Comparative Example 3

A procedure in Comparative Example 3 was similar to that in Example 1 except that low-temperature rapid charge was not performed and storage was performed. In Comparative Example 3, when the voltage difference was calculated after storage, the voltage difference became equal to or greater than a threshold value for the first time on the 70th day, and a target battery was detected.

### Comparative Example 4

Graphite was prepared as a negative electrode active material. CMC and SBR were prepared as binders. The graphite, the CMC, and the SBR were put in pure water as a solvent at a mixing ratio of 97 parts by mass:1.5 parts by mass:1.5 parts by mass, followed by stirring to obtain a slurry. Subsequent steps were performed in the same manner as in Example 1. In Comparative Example 4, when the voltage difference was calculated after storage, the voltage difference became equal to or greater than a threshold value for the first time on the fifth day, and a target battery was detected.

TABLE 1

| | | | | Current applying | | Number of days | |
|---|---|---|---|---|---|---|---|
| | | Temperature of | Current | time in low- | | until target | |
| | Kind of | low-temperature | value of | temperature | Temperature | battery is | |
| | active | rapid charge | low-temperature | rapid charge | of storage | detected | Capacity |
| | material | [° C.] | rapid charge | [s] | [° C.] | [day] | retention rate |
| Example 1 | Nb₂TiO₇ | −20 | 1x | 10 | 60 | 10 | 0.98 |
| Example 2 | Nb₂TiO₇ | 0 | 1x | 10 | 60 | 10 | 0.98 |
| Example 3 | Nb₂TiO₇ | 25 | 1x | 10 | 60 | 10 | 0.98 |
| Example 4 | Nb₂TiO₇ | −20 | 1x | 10 | 45 | 10 | 0.98 |
| Example 5 | Nb₂TiO₇ | −20 | 1x | 10 | 70 | 10 | 0.96 |
| Example 6 | TLO | −20 | 0.5x | 10 | 60 | 10 | 1 |
| Comparative | Nb₂TiO₇ | −20 | 1x | 10 | 80 | 5 | 0.88 |
| Example 1 | | | | | | | |
| Comparative | Nb₂TiO₇ | −20 | 1x | 10 | 25 | 45 | 0.99 |
| Example 2 | | | | | | | |
| Comparative | Nb₂TiO₇ | — | — | — | 45 | 70 | 0.98 |
| Example 3 | | | | | | | |
| Comparative | C | −20 | 1x | 10 | 60 | 5 | 0.41 |
| Example 4 | | | | | | | |

Comparison of Example 1 to Example 6 with Comparative Example 1 and Comparative Example 2 shows that when the temperature of storage after low-temperature rapid charge is within the range of 45° C. or higher and 70° C. or lower, a time required to detect a target battery can be shortened while suppressing a decrease in the capacity retention rate of a non-target battery. This is because when the temperature is 45° C. or higher, the growth of a foreign matter can be accelerated, and when the temperature is 70° C. or lower, deterioration in the electrolyte caused by the decomposition reaction of the electrolyte by the positive and negative electrodes can be suppressed. In Comparative Example 1, the number of days until the target battery is detected is as short as five days, but unlike Examples 1, 4, and 5, it can be seen from the decrease in the capacity retention rate that deterioration occurs also in the non-target battery. This is considered to be because the deterioration in the electrolyte caused by the decomposition reaction of the electrolyte by the positive and negative electrodes cannot be suppressed because the temperature of storage after low-temperature rapid charge exceeds 70° C. In Comparative Example 2, the decrease in the capacity retention rate is suppressed, and therefore it is found that the deterioration in the performance of the non-target battery is suppressed. However, in Comparative Example 2, the storage temperature is lower than 45° C., and therefore it is found that the growth of a foreign matter contained in the target battery cannot be sufficiently accelerated, and the target battery cannot be detected in a short time.

Comparison of Example 1 with Example 5 shows that in Example 1 in which the storage temperature is in a more preferable range of 50° C. or higher and 60° C. or lower, the decrease in the capacity retention rate of the non-target battery can be further suppressed.

Comparison of Examples 1 to 6 with Comparative Example 3 shows that a time for detecting a target cell can be shortened by performing storage after low-temperature rapid charge as in Examples 1 to 6. This is because by rapidly charging the battery at a low temperature, the growth of the foreign matter present on the negative electrode into crystals like dendrites can be promoted. Meanwhile, in Comparative Example 3, the decrease in the capacity retention rate is suppressed, and therefore it is found that the deterioration in the performance of the non-target battery is suppressed. However, in Comparative Example 3, the low-temperature rapid charge is not performed, and therefore it is found that the crystal growth of the foreign matter as described above cannot be sufficiently promoted, and the target battery cannot be detected in a short time.

Comparison of Examples 1 to 6 with Comparative Example 4 shows that when the diagnosis method in the present embodiment is used in the battery using graphite as the active material as in Comparative Example 4, the capacity retention rate of the non-target battery is lower than that of Examples 1 to 6. This is considered to be because the precipitation of lithium occurs due to the low-temperature rapid charge, resulting in a short circuit, so that the capacity retention ratio is lowered in the non-target battery. As described above, by using the secondary battery diagnosis method according to the present embodiment, the target cell is detected in a short time, and the performance of the non-target cell is not deteriorated.

As described above, the present embodiment provides a secondary battery diagnosis method including: rapidly charging a secondary battery at a low temperature; storing the secondary battery in a range of 45° C. or higher and 70° C. or lower for a predetermined period; and determining a degree of voltage drop of the secondary battery before and after storing the secondary battery. The secondary battery includes a negative electrode in which an active material having an average operating potential of 1.0 VvsLi/Li⁺ or more occupies 50% by weight or more of a total weight of a negative electrode active material-containing layer. According to this secondary battery diagnosis method, the performance of a non-target battery is not deteriorated, and a target battery can be detected in a short time, so that a battery having better performance can be provided.

The C rate for rapid charging may be 2C or more, for example, 5C or more.

The calculation section 305 and determination section 306 in FIGS. 8 and 9 may be implemented as follows. For example, the second battery diagnosis device 300 includes a processor such as a CPU (Central Processing Unit) or a GPU (Graphics Processing Unit), a main memory such as a RAM (Random Access Memory) that functions as a work area for the processor, and a program memory such as a ROM (Read Only Memory) that stores a control program. Each function of the calculation section 305 and determination section 306 is realized in the second battery diagnosis device 300 by the processor reading out the control program stored in the program memory onto the main memory and executing it. Part or all of the functions of the calculation section 305 and determination section 306 may be realized using dedicated hardware such as ASIC (Application Specific Integrated Circuit) or FPGA (Field Programmable Gate Array). [0120]Although some embodiments of the present invention have been described, these embodiments have been presented as examples, and are not intended to limit the scope of the invention. These novel embodiments can be implemented in various other forms, and various omissions, substitutions, and changes can be made without departing from the gist of the invention. These embodiments and modifications thereof are included in the scope and gist of the invention, and are included in the invention described in the claims and the equivalent scope thereof.

Hereinafter, the invention according to the embodiment will be additionally described.

[1]

A secondary battery diagnosis method including:
rapidly charging a secondary battery at a low temperature;
storing the secondary battery in a range of 45° C. or higher and 70° C. or lower for a predetermined period; and
determining a degree of voltage drop of the secondary battery between before and after storing the secondary battery,
wherein the secondary battery includes a negative electrode in which an active material having an average operating potential of 1.0 VvsLi/Li⁺ or more occupies 50% by weight or more of a total weight of a negative electrode active material-containing layer.

[2]

The secondary battery diagnosis method according to [1], wherein the secondary battery is stored for 240 hours.

[3]

The secondary battery diagnosis method according to [1] or [2], wherein the secondary battery is rapidly charged at a low temperature under a condition SOC 90% in a range of −25° C. or higher and 25° C. or lower at a constant current value of 0.4x or more and 1.3x or less for 10 seconds or more and 30 seconds or less, where x (mA/cm2) is a value obtained by dividing a current value corresponding to 10 C with respect to a cell capacity by an electrode facing area.

[4]

The secondary battery diagnosis method according to any one of [1] to [3], wherein a difference between a voltage V0 of the secondary battery before start of the storage and a voltage V1 of the secondary battery after the storage for a predetermined period is calculated, and when the difference is equal to or greater than a threshold value, the secondary battery is determined to be a target battery.

[5]

The secondary battery diagnosis method according to any one of [1] to [4], wherein the threshold value is 0.05 V.

[6]

A secondary battery diagnosis device including: a secondary battery rapidly charged at a low temperature; a voltage measuring section that measures a voltage V0 of the secondary battery before start of storage and a voltage V1 of the secondary battery after the storage for a predetermined period, for the secondary battery stored for a predetermined period in a range of 45° C. or higher and 70° C. or lower; a first memory that memorizes the voltage V0 and the voltage V1; a calculating section that calculates a difference between the voltage V0 and the voltage V1; and a determining section that determines that the secondary battery is a target battery when the value calculated by the calculating section is equal to or greater than a threshold value, wherein the secondary battery includes a negative electrode in which an active material having an average operating potential of 1.0 VvsLi/Li⁺ or more occupies 50% by weight or more of a total weight of a negative electrode active material-containing layer.

[7]

The secondary battery diagnosis device according to [6], wherein the secondary battery is rapidly charged at a low temperature under a condition SOC 90% in a range of −25° C. or higher and 25° C. or lower at a constant current value of 0.4x or more and 1.3x or less for 10 seconds or more and 30 seconds or less, where x (mA/cm²) is a value obtained by dividing a current value corresponding to 10 C with respect to a cell capacity by an electrode facing area.

[8]

The secondary battery diagnosis device according to [6] or [7], wherein the threshold value is 0.05 V.

[9]

A secondary battery diagnosis system including: a charging section configured to rapidly charge a secondary battery at a low temperature; a storing section that stores the secondary battery after being rapidly charged at a low temperature; and the secondary battery diagnosis device according to any one of [6] to [8].

What is claimed is:

1. A secondary battery diagnosis method comprising:
rapidly charging a secondary battery at a low temperature;
storing the secondary battery in a range of 45° C. or higher and 70° C. or lower for a predetermined period; and
determining a degree of voltage drop of the secondary battery between before and after storing the secondary battery,
wherein the secondary battery includes a negative electrode in which an active material having an average operating potential of 1.0 VvsLi/Li⁺ or more occupies 50% by weight or more of a total weight of a negative electrode active material-containing layer.

2. The secondary battery diagnosis method according to claim 1, wherein the secondary battery is stored for 240 hours.

3. The secondary battery diagnosis method according to claim 1, wherein the secondary battery is rapidly charged at a low temperature under a condition SOC 90% in a range of −25° C. or higher and 25° C. or lower at a constant current value of 0.4x or more and 1.3x or less for 10 seconds or more and 30 seconds or less, where x (mA/cm²) is a value obtained by dividing a current value corresponding to 10 C with respect to a cell capacity by an electrode facing area.

4. The secondary battery diagnosis method according to claim 1, wherein a difference between a voltage V0 of the secondary battery before start of the storage and a voltage V1 of the secondary battery after the storage for a predetermined period is calculated, and when the difference is equal to or greater than a threshold value, the secondary battery is determined to be a target battery.

5. The secondary battery diagnosis method according to claim 4, wherein the threshold value is 0.05 V.

6. A secondary battery diagnosis device comprising:
a secondary battery rapidly charged at a low temperature;
a voltage measuring section that measures a voltage V0 of the secondary battery before start of storage and a voltage V1 of the secondary battery after the storage for a predetermined period, for the secondary battery stored for a predetermined period in a range of 45° C. or higher and 70° C. or lower;
a first memory that memorizes the voltage V0 and the voltage V1;
a calculating section that calculates a difference between the voltage V0 and the voltage V1; and
a determining section that determines that the secondary battery is a target battery when the value calculated by the calculating section is equal to or greater than a threshold value,
wherein the secondary battery includes a negative electrode in which an active material having an average operating potential of 1.0 VvsLi/Li⁺ or more occupies 50% by weight or more of a total weight of a negative electrode active material-containing layer.

7. The secondary battery diagnosis device according to claim 6, wherein the secondary battery is rapidly charged at a low temperature under a condition SOC 90% in a range of −25° C. or higher and 25° C. or lower at a constant current value of 0.4x or more and 1.3x or less for 10 seconds or more and 30 seconds or less, where x (mA/cm²) is a value obtained by dividing a current value corresponding to 10 C with respect to a cell capacity by an electrode facing area.

8. The secondary battery diagnosis device according to claim 6, wherein the threshold value is 0.05 V.

9. A secondary battery diagnosis system comprising:
a charging section configured to rapidly charge a secondary battery at a low temperature;
a storing section that stores the secondary battery after being rapidly charged at a low temperature; and
the secondary battery diagnosis device according to claim 6.
